(19) United States
(12) Patent Application Publication
(10) Pub. No.: US 2010/0267231 A1
(43) Pub. Date: Oct. 21, 2010

(54) APPARATUS FOR UV DAMAGE REPAIR OF LOW K FILMS PRIOR TO COPPER BARRIER DEPOSITION

(76) Inventors: Bart van Schravendijk, Sunnyvale, CA (US); Victoria Shannon Benzing, Saratoga, CA (US)

Correspondence Address: Weaver Austin Villeneuve & Sampson LLP - NOVL;Attn.: Novellus Systems, Inc., P.O. Box 70250, Oakland, CA, 94612-0250, US

(21) Appl. No.: 12/726,263

(22) Filed: Mar. 17, 2010

Related U.S. Application Data
(63) Continuation-in-part of application No. 11/590,661, filed on Oct. 30, 2006.
Application No. 11/590,661 is a continuation-in-part of application No. 12/646,830, filed on Dec. 23, 2009.

(51) Int. Cl. H01L 21/768; C23C 16/06; C23C 14/34

(52) U.S. Cl. 438/653; 118/697; 204/298.25; 257/E21.584

(57) ABSTRACT

An apparatus and method for the ultraviolet (UV) treatment of carbon-containing low-k dielectric enables process-induced damage repair. A semiconductor substrate processing system may be configured to include degas and plasma pre-clean modules, UV process modules, copper diffusion barrier deposition modules and copper seed deposition modules such that the substrate is held under vacuum and is not exposed to ambient air after low k damage repair and before copper barrier layer deposition. Inventive methods provide for treatment of a damaged low-k dielectric on a semiconductor substrate with UV radiation to repair processing induced damage and barrier layer deposition prior breaking vacuum.

### CROSS-REFERENCE TO RELATED APPLICATIONS

This application is a continuation-in-part of U.S. patent application Ser. No. 11/590,661 filed Oct. 30, 2006, titled UV TREATMENT FOR CARBON-CONTAINING LOW-K DIELECTRIC REPAIR IN SEMICONDUCTOR PROCESSING, and U.S. patent application Ser. No. 12/646,830 filed Dec. 23, 2009, titled UV AND REDUCING TREATMENT FOR K RECOVERY AND SURFACE CLEAN IN SEMICONDUCTOR PROCESSING, incorporated herein by reference in their entirety for all purposes.

### FIELD OF THE INVENTION

The invention relates to semiconductor processing, particularly to apparatus and methods to deposit and treat low dielectric constant layers. More specifically, the invention relates to an apparatus for UV treatment for repair of process-induced damage of low dielectric constant dielectric materials in, for example, damascene processing.

### BACKGROUND

Ultrafine feature sizes and high performance requirements have necessitated the integration of low dielectric constant (low-k) insulating materials, that are mechanically weaker than previous generation materials, into semiconductor devices. The inherently weak nature of the low-k dielectric material can pose significant challenges for downstream electronic-packaging processes and material compatibility.

Low-k materials are, by definition, those semiconductor-grade insulating materials that have a dielectric constant (“k”) lower than that of SiO₂, i.e., 3.9. Various types of low-k materials can have dielectric constants ranging from about 3.8-3.6 (e.g., fluorosilicate glass (FSG)), to less than about 3.2 (e.g., (carbon doped oxide (CDO)), to as low as 2.2 (e.g., spin-on glass (SOG)) or even lower, and encompass low-k dielectrics referred to as “ultra low-k” (ULK) and “extreme ultra low-k” (ELK). In many CDO carbon-containing low-k implementations, such as are described herein, suitable carbon-containing low-k materials have a dielectric constant of about 2.7 or lower. To further reduce the size of devices on integrated circuits, it has become necessary to use conductive materials having low resistivity and insulators having low dielectric constants to reduce the capacitive coupling between adjacent metal lines. Low-k materials are being integrated into the devices to improve device performance and allow for device scaling.

Low-k materials are less dense than standard insulating materials such as SiO₂. This introduces a host of process integration and material compatibility difficulties. The balance between maintaining the film's integrity and integrating it properly and performing the necessary stripping, cleaning, and conditioning gets increasingly precarious. Patterning processes (etching, stripping, deposition, and cleaning) can also have a drastic impact on the integrity of carbon-containing low-k materials, in particular SiOC-based low-k materials.

The properties that give carbon-containing low-k dielectric materials their desirable low dielectric constants are the very same properties that are leading to significant integration challenges. Carbon-containing low-k materials achieve lower dielectric constants through the incorporation of non-polar covalent bonds (e.g., from the addition of carbon) and the introduction of porosity to decrease film density. Introducing porosity or the incorporation of terminal bonds, such as Si—CH₃, breaks the continuity of the rigid Si—O—Si lattice of traditional oxides, yielding a lower dielectric constant film that is both mechanically and chemically weaker. Because of the mechanical weakness, carbon-containing low-k films are susceptible to kinetic plasma damage that can undesirably densify the film and thus increase the film's effective k value.

Furthermore, chemical plasmas can modify carbon-containing low-k films where bonds such as Si—CH₃ are readily broken. The susceptibility of carbon-containing low-k materials to plasma modification poses a serious integration challenge since plasma processes are routinely used to etch, clean, and deposit films in the manufacturing of a semiconductor device. Moreover, in damascene processing, prior to metal barrier deposition, process induced carbon-containing low-k dielectric damage can be incurred from etch, dry resist strip, wet cleaning and dry (plasma) cleaning Carbon-containing low-k materials are also susceptible to the intercalation of plasma species, residues, solvents, moisture, and precursor molecules that can either adsorb into, outgas from, or chemically modify the film.

Damage to the carbon-containing low-k dielectric material on the sidewalls or bottoms of the vias and trenches or in the inter-layer dielectric (ILD) regions during copper (Cu) damascene processing can compromise the integrity of the dielectric, leading to increased leakage, higher capacitance, and reduced performance and reliability. The damaged low-k layers can absorb moisture in ambient air, which may remain trapped in the dielectric. This can also oxidize the barrier material leading to Cu diffusion. Damage of the low-k dielectric material is linked to the loss of methyl groups (CH₃) in the film during processing. Thus, dielectric repair to prevent the unwanted absorption of moisture and to remove absorbed moisture is important.

Carbon depletion occurs when, for example, a Si—CH₃ bond is broken leaving a silicon dangling bond. Reaction with absorbed water from atmospheric exposure or wet processing results in the formation of highly polarizable silanol (Si—OH) groups, which leads to an increase in k value for the damaged portion of the film, thus increasing the effective k value of the dielectric significantly. A higher effective k value leads to higher intra- and interlayer capacitance, reducing performance as well as reliability.

Because of this, semiconductor manufacturers have developed methods to eliminate carbon depletion or replenish (repair) the depleted carbon. One method is the use of chemicals called “Toughening Agents” (TA) to repair carbon depletion damage. Another method is to use sacrificial capping layers to protect the low-k films from carbon depletion. However, neither of these methods is applicable to treat via and trench sidewall damage or trench bottom damage just prior to metal barrier deposition, which is particularly challenging because the underlying metal interconnect is necessarily exposed at this point in the process flow. The exposure of the metal means that damaging reactions with this metal surface must be avoided to limit degradation of contact resistance and interconnect reliability. Thus, improved methods and apparatus for low-k dielectric repair in semiconductor processing are needed.

### SUMMARY OF THE INVENTION

The present invention provides apparatuses and methods for the ultraviolet (UV) treatment of carbon-containing low-k dielectric, for example, but not limited to, carbon-doped oxide (CDO), for the repair of process-induced damage. A semiconductor processing system may be configured to include degas and plasma pre-clean modules, UV process modules, copper diffusion barrier deposition modules, and copper seed deposition modules such that the substrate is held under vacuum and is not exposed to ambient air after low k damage repair and before copper barrier layer deposition. Inventive methods provide for treatment of a damaged low-k dielectric on a semiconductor substrate with UV radiation to repair processing induced damage. The method is particularly applicable in the context of damascene processing.

In one aspect, the invention pertains to a semiconductor processing apparatus having an ultraviolet (UV) process module. The apparatus may include a load lock, a transport module, a robot, and a plurality of process modules including a UV process module and at least one metal (e.g., copper) deposition module that can include one of more of a copper diffusion barrier deposition module and a copper seed deposition module. The transport module may include a load chamber, a transfer chamber, and a pass-through chamber located between the load chamber and the transfer chamber. The load chamber may be coupled to the load lock. The robot may be configured to transfer a wafer between the load lock and the load chamber. A first set of process modules may be coupled to the load chamber; and, a second set of process modules may be coupled to the transfer chamber. At least one of the process modules in the first or second set may be a UV process module. Each process module may be configured to process one wafer at a time.

The apparatus may also include an intermediate process module coupled to the load chamber and the transfer chamber. This intermediate process module may be a degas module, a UV module, or a combination of degas and UV module. Wafers may enter the intermediate process module from the load chamber and exit through the transfer chamber or vice versa.

The first set of process modules may include one or more UV process modules and/or one or more metal deposition modules, such as copper deposition modules. A copper deposition module may be configured to deposit a copper barrier layer or a copper seed layer. Examples of suitable copper barrier layers are Ta, TaN, Ti, TiN, WN, and various combinations thereof. A second set of process modules may include a UV process module, a pre-clean module, a chemical vapor deposition module, an atomic layer deposition module, or a physical vapor deposition module.

The UV process module may include a temperature controlled substrate holder and one or more UV light sources. The UV light sources may be configured to generate UV radiation with a power density of about 500 mW-5 W/cm² and a wavelength from about 150-500 nm. The UV process module may also have a gas inlet for injecting reactant and carrier gases and a vacuum outlet to evacuate the module. The UV light source may be an array of UV sources, such as lamps and lasers. These sources may be mercury vapor lamps, xenon lamps, deuterium lamps, excimer lamps, excimer lasers, and combinations of these. Each array or each source may be configured to generate a different wavelength distribution. The module may also include a movable mount for the UV light source configured to change the orientation of the UV light relative to the wafer, either during the exposure or adjustable for each exposure. The UV process module may also include a reflector, a filter, a scanning optical system, or a combination of these to control the UV light characteristics at the wafer surface.

In another aspect, the invention relates to a method of processing a semiconductor device, for example in the context of damascene processing. The method may include depositing a carbon-containing low-k dielectric layer on a wafer; etching a trench in the dielectric layer, the trench having sidewalls and a bottom; exposing the trench to UV radiation in a process module coupled to a transfer chamber; depositing a barrier layer on the wafer in a process module coupled to a transfer chamber; and, depositing a copper seed layer on the wafer in a process module coupled to a load chamber. The method may be performed such that the wafer is not exposed to ambient conditions (i.e., no breaking vacuum or maintaining an inert gas environment) after the UV exposure operations and before the copper barrier layer deposition. Exposing the trench to UV radiation repairs damage (e.g., dangling bonds or highly strained bonds, e.g., Si—O—Si, Si—OH, or Si—CH₂—Si, caused by removal of organic (generally —CH₃) groups) to the low-k material of the trench sidewalls and bottom caused by the trench formation process (generally etching, ashing, and wet or dry cleaning)). Low-k dielectric layers may absorb moisture in the ambient environment and trap the moisture. If not removed, the trapped moisture may oxidize the barrier material and lead to copper diffusion.

This may be accomplished by performing the UV exposing, barrier layer depositing, and the copper seed layer deposition operations in the same semiconductor processing tool under a reduced pressure (vacuum) environment. The method may also include pre-cleaning the wafer and exposing the wafer to UV radiation while degassing the wafer in the same semiconductor processing tool. Another advantage of performing these operations in the same tool is that damage to the low-k dielectric layer caused by pre-cleaning the wafer may be repaired before the barrier layer deposition. While the invention is not limited to this theory of operation, it is believed that the UV exposure of the damaged dielectric surface according to this aspect of the invention cross-links the surface Si groups to fill gaps from the departed methyl (—CH₃) groups. In some cases, the UV exposure cleaves silanol bonds (Si—OH) and cross-links the film Si groups to form a densified surface layer.

In certain embodiments, the UV exposure may be conducted in a partial pressure of a reactive gas that participates in dielectric repair. An appropriate gas may include, for example, a gas phase source of methyl (—CH₃) groups during the UV exposure. Exposure time should be limited in order to prevent further damage of the dielectric (e.g. excessive crosslinking and densification). In general, the dose time should be for no more than 10 seconds and/or result in a penetration of no more than four to five monolayers of the dielectric. A preferred dose time is about one to two seconds. Suitable gas phase reactants include, preferably, organo-silanes, -silazanes, and -siloxanes, for example, dichlorodimethylsilane (DCDMS), chlorotrimethylsilane (CTMS), hexamethyldisilazane (HMDS), hexamethyldisiloxane (HMDSO), tetravinyltetramethylcyclotetrasiloxane (TVTMCTS)). Other suitable gas phase reactants include acetaldehyde; alkanes, for example methane and ethane; alkenes, for example ethylene; and alkynes, for example acetylene, may also be used. —H and —O groups may also participate in suitable repair reactions. In that case, —H and —O may be provided in one or more gas phase reactants or may evolve from the film. The gas phase may also include inert carriers such as He, Ar, Ne, N₂, etc.

While the invention is not limited to this theory of operation, it is believed that damage sites, including dangling Si bonds, silanol bonds (Si—OH), and/or highly strained bonds (e.g., Si—O—Si or Si—CH₂—Si) in the carbon-containing dielectric film are satisfied with a methyl group from methyl-containing molecules of the gas phase source of methyl (—CH₃) groups in a reaction induced by the activation provided by UV radiation, thereby accomplishing low-k dielectric repair without substantial alteration of dielectric properties. In some instances, active methyl (—CH₃) groups may be generated by dissociation of methyl-containing molecules of the gas phase source of —CH₃ groups by the UV radiation. Alternatively, methyl groups in methyl-containing molecules in the gas phase source of —CH₃ groups can react with damage sites in the film. The reaction of the activated methyl groups with the damaged area of the film when the activation energy is lowered by the UV radiation reduces the energy of film, rendering it more stable.

In certain embodiments, the UV exposure also may be conducted in a partial pressure of a reducing agent that participates in dielectric repair. An appropriate reducing agent gas may include, for example, ammonia (NH₃) or hydrogen (H₂) gas.

The invention may also be more generally applicable in other semiconductor processing contexts. For example, a method of forming a semiconductor device, may involve depositing a carbon-containing low-k dielectric layer on a substrate, conducting a semiconductor processing operation that damages the low-k dielectric layer, and exposing the low-k dielectric layer to UV radiation such that processing-induced low-k dielectric damage to the dielectric is repaired. The operation that damages the low-k dielectric layer may be performed in the same semiconductor processing tool that repairs the damage to avoid effects from intermediate exposure to ambient conditions or other processing conditions.

These and other features and advantages of the present invention will be described in more detail below with reference to the associated drawings.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a process flow chart depicting a method in accordance with an embodiment of the invention.

FIGS. 2A-2D are cross-sectional diagrams illustrating the formation of a semiconductor device in accordance with an embodiment of the invention.

FIG. 3 is a schematic diagram of an example UV light source and chamber suitable for implementing the present invention.

FIGS. 4A-C are schematic diagrams of semiconductor processing apparatus in accordance with the present invention.

### DETAILED DESCRIPTION

Embodiments of the present invention are described herein in the context of a UV treatment for carbon-containing low-k dielectric repair in damascene processing. Those skilled in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

The term “semiconductor device” as used herein refers to any device formed on a semiconductor substrate or any device possessing a semiconductor material. In many cases, a semiconductor device participates in electronic logic or memory, or in energy conversion. The term “semiconductor device” subsumes partially fabricated devices (such as partially fabricated integrated circuits) as well as completed devices available for sale or installed in particular apparatus. In short, a semiconductor device may exist at any state of manufacture that employs a method of this invention or possesses a structure of this invention. The terms “wafer” and “substrate” refers to the work pieces on which processing may be performed and may be used interchangeably in this disclosure.

As noted above, the present invention provides a method for the ultraviolet (UV) treatment of carbon-containing low-k dielectric for the repair of process-induced damage. Applicable carbon containing dielectrics typically have SiO-based backbones doped with carbon, in particular CDO (for example, those formed from octamethyl cyclotetrasiloxane (OMCTS), tetramethylcyclotetrasiloxane (TMCTS), dimethyldimethoxysilane (DMDMOS), and diethoxymethylsilane (DEMS) and other known CDO precursors), but may also include hybrid polymers incorporating both C, Si and O in the backbone. Inventive methods provide for treatment of a damaged carbon-containing low-k dielectric on a semiconductor substrate with UV radiation to repair processing induced damage. The method is particularly applicable in the context of damascene processing.

In one aspect, the invention relates to a method of forming a semiconductor device by depositing a carbon-containing low-k dielectric layer on a substrate and forming a via and trench in the low-k dielectric layer, the trench having sidewalls ending at a bottom. The trench is then exposed to UV radiation to repair process induced low-k dielectric damage (e.g., dangling bonds or highly strained bonds, e.g., Si—O—Si or Si—CH₂—Si, caused by removal of organic (generally —CH₃) groups) to the low-k material of the trench sidewalls and bottom caused by etch, dry resist strip, wet cleaning and dry cleaning, for example, involved in the trench formation process. The repaired damascene trench can then be filled with a conductive material, particularly a metal diffusion barrier followed by copper. The top surface of the semiconductor device can then be planarized, generally by chemical mechanical polishing (CMP). Post-planarization UV repair of planarization-induced dielectric damage may also be conducted.

### Process

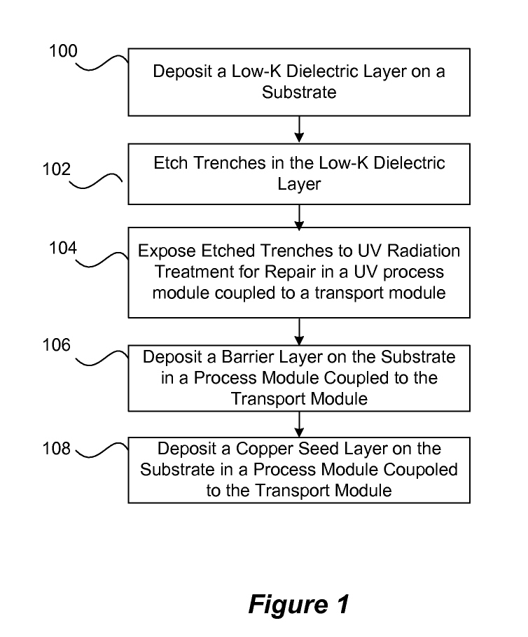

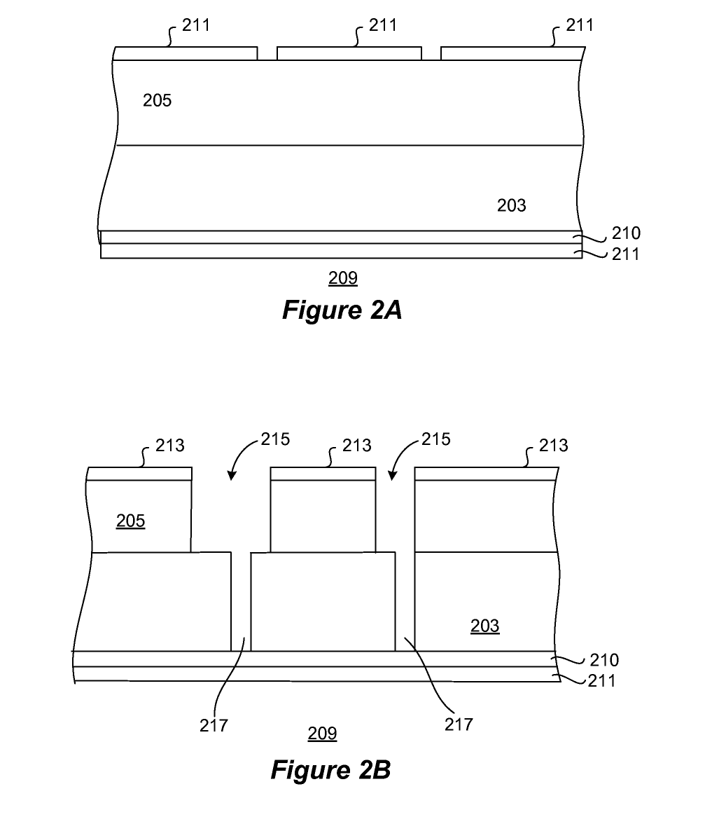

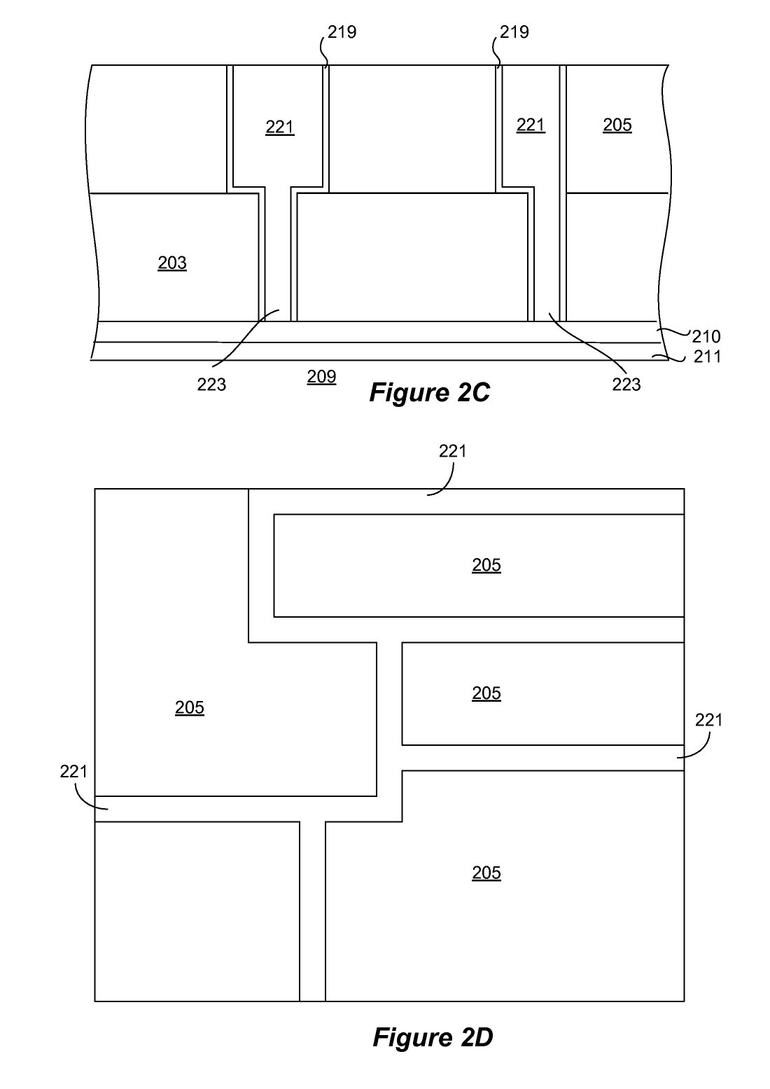

FIG. 1 is a process flow chart depicting operations that may be performed in various methods in accordance with embodiments of the present invention. The figure and accompanying description also provide an operational context for methods and apparatus in accordance with embodiments of the invention to facilitate its description. The invention is advantageously applied in a damascene processing context, although its application is not so limited. It should be understood that, in at least some method aspects, the present invention requires only a UV radiation treatment of an applicable semiconductor device substrate such as described in operation 104 of the embodiment illustrated in FIG. 1. Other aspects of the invention or an operational context for the invention may include additional processing operations, such as damascene processing operations described herein. But the invention is not limited to the performance of these additional processing operations in all its aspects. A generalized version of a dual damascene technique is described below with reference to FIGS. 2A through 2D, which depict a partially formed semiconductor device during various stages of this process, again to provide an advantageous implementation or operational context for methods and apparatus in accordance with embodiments of the invention to facilitate its description. The invention may also be used in conjunction with other semiconductor processing techniques.

Referring now to FIG. 1, in operations that are not necessarily part of the present invention, but place an embodiment of the invention in context in an advantageous application, a carbon-containing low-k dielectric layer is deposited on a substrate at 100. Patterns of conductive features are formed in the dielectric layer, generally by plasma etching, at 102. Plasma etching generally results in damage to the pattern edges, generally trench sidewalls and bottoms, as described above. Other process operations, such as dry resist strip, wet cleaning and dry cleaning, can also cause or contribute to low-k dielectric damage. The conductive features are typically, though not necessarily, metal lines and vias. In one example, they are the interconnects of a metallization layer that is formed from copper. As is known to those of skill in the art, various techniques may be employed to form such layers.

After the features are formed in the low-k dielectric layer, the features are filled with a conductive material, e.g., copper or other metal. Because copper can diffuse into the dielectric layer and cause device failure, generally a diffusion barrier layer is deposited before the copper. This barrier layer may be tantalum, tantalum nitride, Ti, TiN, WN, Co or other suitable materials or compounds. Further, a CVD or PVD copper or Ru seed layer may be deposited before a bulk copper deposition, generally by electroplating. The barrier layer and seed layer deposition generally occur in the same semiconductor processing tool that generally does not perform the feature formation operations of 102, e.g., etching.

The substrate may be introduced to a copper barrier/seed processing tool after the features are formed and before the damage has been repaired. A degas module may heat the substrate and remove any gaseous compounds released. In some embodiments, the degas module may be configured with UV light sources and may initiate low-k dielectric repair. In certain embodiments, the substrate is pre-cleaned after the degas module. The pre-clean module applies a plasma or other reactive ambient to remove any contaminants and oxidation from the substrate surface. The pre-clean operation may further damage the low-k dielectric layer. An advantage of the present invention is facilitation of repair not only damage caused by the feature formation, e.g., etching, but also to repair damage from the pre-clean operations before the barrier deposition.

The etched trenches are then exposed to ultraviolet (UV) radiation at 104. The UV exposure may be conducted in vacuum or with reactive gases. Suitable UV treatment parameters are in the power intensity range of about 1 mW-20 W/cm², preferably about 500 mW-5 W/cm²; at a wavelength of about 150-500 nm, preferably about 200-400 nm; for up to about 2 minutes; at a wafer temperature of between room temperature up to about 450° C., preferably about 100-400° C. A typical UV exposure in accordance with this aspect of the invention has a power density of about 1-3 W/cm² for a duration of about 10-30 seconds; at a wafer temperature of about 350° C. in either inert (e.g., He, Ar, or N₂) or reactive environments (e.g., in an anneal environment that comprises one or more of hydrogen, ammonia or other reducing agents, oxygen, ozone, water, peroxide, atomic oxygen, nitrous oxide or other oxidants). In reactive environments, the reactants can promote bond breaking thereby facilitating hydrogen removal for film repair. The UV source can be a single wavelength excimer lamp or broad spectrum source with arc or microwave excitations. The process pressure can range from about 1 mTorr to 760 Torr, preferably from about 1 Torr to 200 Torr. The UV exposure may also occur concurrently to a downstream or very low effective power plasma treatment with He, Ar, Ne, N₂, H₂, NH₃, N₂O, O₂, H₂O or a mixture of them.

While the invention is not limited to any particular theory of operation, it is believed that the UV exposure of the damaged dielectric surface according to this aspect of the invention cross-links the surface Si groups to fill gaps from the departed methyl (—CH₃) groups.

In certain embodiments, the UV exposure may be conducted in a partial pressure of a reactive gas that participates in dielectric repair. An appropriate gas will have a gas phase source of methyl (—CH₃) groups during the UV exposure. Exposure time should be limited in order to prevent the stripping of methyl groups from the dielectric or dielectric shrinking (which causes stress and strain in the film). In general, the dose time should be for no more than 120 seconds depending on dose and wafer temperature. A preferred dose time is 10-30 seconds. Suitable gas phase reactants include, preferably, organo-silanes, -silazanes, and -siloxanes, for example, dichlorodimethylsilane (DCDMS), chlorotrimethylsilane (CTMS), hexamethyldisilazane (HMDS), hexamethyldisiloxane (HMDSO), tetravinyltetramethylcyclotetrasiloxane (TVTMCTS)). Other suitable gas phase reactants include acetaldehyde; alkanes, for example methane and ethane; alkenes, for example ethylene; and alkynes, for example acetylene, may also be used. —H and —O groups may also participate in suitable repair reactions. In that case, —H and —O may be provided in one or more gas phase reactants or may evolve from the film. The gas phase may also include inert carriers such as He, Ar, Ne, N₂, etc.

While the invention is not limited to this theory of operation, it is believed that damage sites, including dangling Si bonds, silanol bonds, and/or highly strained bonds (e.g., Si—O—Si or Si—CH₂—Si) in the carbon-containing low-k dielectric film are satisfied with a methyl group from the gas phase source of —CH₃ groups in a reaction induced by the activation provided by UV radiation, thereby accomplishing low-k dielectric repair without substantial alteration of dielectric properties. In some instances, active methyl (—CH₃) groups may be generated by dissociation of methyl-containing molecules in the gas phase source of —CH₃ groups by the UV radiation. Alternatively, methyl groups in methyl-containing molecules in the gas phase source of —CH₃ groups can react with damage sites in the film. The reaction of activated methyl with the damage surface site can occur when UV radiation excites electrons into anti-bonding states, lowering the thermal activation energy of the reaction. This renders the film more stable.

Anything other than a carbon group reacting with a damage site on the surface of the dielectric will produce a higher k than the original low-k film. However, in instances where a minimal k value of the dielectric is not required, this rise in effective k resulting from non-carbon-containing repair (e.g., UV exposure alone) may be acceptable.

In certain embodiments, the UV exposure also may be conducted in a partial pressure of a reducing agent that participates in dielectric repair, such as described in U.S. patent application Ser. No. 12/646,830, incorporated by reference herein for this purpose. An appropriate reducing agent gas may include, for example, ammonia (NH₃) or hydrogen (H₂) gas.

The UV light may be irradiated on the sidewalls and bottom of the trench to repair the damage from the etching of the trenches. The photon energy supplied by the UV treatment effectively lowers the activation barrier for reaction, and depleted methyl sites within the films are filled by a reaction with the active methyl groups derived from the gas phase source of methyl (—CH₃) groups. Satisfying the Si dangling bonds in the damaged film repairs the damage done to the low-k dielectric during the trench formation process (e.g., etching, ashing, and wet or dry cleaning) without substantially altering the dielectric properties. In addition, there may be silanol groups (—OH) in the damaged areas that are formed from Si dangling bonds that are exposed to moisture, either in subsequent processing or from moisture present in the fab ambient atmosphere. These silanol bonds are cleaved during the UV treatment, and the —OH groups leave the film, effectively lowering the dielectric constant and “repairing” the film. Interconnect reliability is thereby improved.

The apparatus employed to implement the invention can have one or more UV light sources. Suitable apparatus are described in more detail below.

Following the low-k dielectric repair in accordance with the present invention, a diffusion barrier film, such as a copper diffusion barrier film, is deposited on the planarized surface of the partially-formed semiconductor device in operation 106. This layer may serve other purposes aside from that of a diffusion barrier. For example, the diffusion barrier film may also act as a CMP stop layer. The diffusion barrier deposition is performed in the same semiconductor processing tool as the UV exposure. In certain embodiments, the UV process module and the barrier deposition module are coupled to a transport module. One particular advantage of the present invention is that the wafer need not exit the vacuum environment before depositing the diffusion barrier film. Thus no opportunity exists for the low-k dielectric film to absorb moisture in ambient environment.

A copper or Ru seed layer may be deposited on the substrate in another process module configured for copper seed deposition in operation 108. The seed layer may be deposited by a physical vapor deposition or chemical vapor deposition module. The seed layer deposition is preferably performed in the same semiconductor processing tool as the UV exposure. In certain embodiments, the UV process module, the barrier deposition module, and the copper seed deposition module are coupled to the same transport module.

Further processing of the substrate is generally performed in a different processing tool after breaking vacuum and removing the substrate from the apparatus in accordance with the present invention. In operations that are not necessarily part of the present invention, the trenches are filled with a conductive material such as copper. This bulk copper deposition is typically performed by electroplating, but also may be a PVD, CVD, or electroless deposition. The electroplating is generally, performed in a separate semiconductor processing tool from the barrier and seed deposition. However, in some embodiments, bulk copper deposition may be performed in the same tool without breaking vacuum.

To complete damascene processing, excess material deposited to ensure complete filling of the trenches is removed from the top of the dielectric layer. The excess material may be removed by a planarization process to form an exposed pattern of conductive features in the dielectric.

Referring now to FIGS. 2A-2D, a typical dual damascene process incorporating processing-induced damage repair processes of the present invention is illustrated. As noted above, it should be understood that an embodiment of the invention in context in an advantageous application is depicted. In at least some aspects, the present invention requires only the UV treatment of the semiconductor device substrate in the same tool with the metal deposition (barrier/seed), as described above.

Referring to FIG. 2A, first 203 and second 205 layers of dielectric are deposited in succession, possibly separated by deposition of an etch stop layer, such as a silicon nitride layer. As is well known in the art, according to alternative damascene processing techniques a single thicker dielectric layer can be used instead of discrete first and second layers.

After deposition of the second dielectric layer 205, a via mask 211 is formed having openings where vias will be subsequently etched. Next, the vias are partially etched down through the level of the second dielectric 205. Then via mask 211 is stripped off and replaced with a line mask 213 as depicted in FIG. 2B. A second etch operation is performed to remove sufficient amounts of dielectric to define line paths 215 in second dielectric layer 205. The etch operation also extends via holes 217 through first dielectric layer 203, down to contact an etch stop layer 210 above a metal layer 211 on the underlying substrate 209.

It should be noted that the foregoing description is just an example of one dual damascene process in connection with which the present invention may be implemented. One type of via-first dual damascene process has been described. In other embodiments, a via-first process may involve complete etching of the vias prior to etching of the line trenches. Or, a trench-first process, in which the etching of the line trenches precedes the via etching, may be used. These various damascene processing techniques, and other variations thereon, are well known in the art and represent alternative implementation contexts for embodiments of the present invention. The invention is also applicable is single damascene processing, more conventional metal deposition and etch, and essentially any semiconductor processing context where carbon-containing low-k dielectrics are used. Further in this regard, the term “trench” in the context of damascene processing is commonly understood to describe a feature formed in dielectric and subsequently filled to form a conductive line in a dielectric layer. In a more general semiconductor processing context, the term is also understood to describe a feature formed in dielectric and subsequently filled to form an element of a semiconductor device (e.g., via, line, STI, etc.), and may include a damascene trench or a combined damascene structure. Unless it is otherwise clear from the context, when used herein, the term should be understood to have its broader meaning.

After trench etching, the photoresist is removed in another plasma process, followed by a wet or dry clean. Then damage on the low-k dielectric surface is repaired by UV treatment and metal deposition operations are performed without breaking vacuum, as discussed above. A thin layer of conductive barrier layer material 219 is formed on the exposed surfaces (including sidewalls) of dielectric layers 203 and 205. Conductive barrier layer material 219 may be formed, for example, of tantalum or tantalum nitride. A CVD or PVD operation is typically employed to deposit conductive barrier layer material 219. Prior to the deposition of the barrier material, a plasma process is typically used to clean the bottoms of the trenches to remove oxidation and contaminants from the exposed copper surface on the underlying layer. As is known to those skilled in the art, this barrier “preclean” plasma process can be simply an inert plasma or a reactive plasma of a gas such as hydrogen. The preclean plasma process can also damage a low-k dielectric film. A UV treatment as described above to repair the damaged low-k film may be employed prior to the PVD operation—for a Ta or TaN barrier layer.

On top of the barrier layer, a conductive metal (typically copper) is deposited in the trench and line paths 217 and 215. Conventionally this deposition is performed in two steps: an initial deposition of a conductive seed layer followed by bulk deposition of copper by electroplating. The seed layer may be deposited by physical vapor deposition, chemical vapor deposition, electroless plating, etc. Note that the bulk deposition of copper not only fills line paths 215 but, to ensure complete filling, also covers all the exposed regions on top of second dielectric layer 205. A semiconductor processing apparatus in accordance with the present invention can accomplish the processing operations up to barrier and seed deposition and possibly trench fill in situ, without breaking vacuum. Once the at least the barrier layer and the seed layer are in place, vacuum can then safely be broken to move the substrate to a different tool for further processing, e.g., CMP.

Thus, a semiconductor processing tool in accordance with the present invention may be configured to include degas and plasma pre-clean modules, UV process modules, copper diffusion barrier deposition modules, and copper seed deposition modules such that the substrate is held under vacuum and is not exposed to ambient air after low k damage repair and before copper barrier layer deposition. The tool can be operated to perform a processing method such that the wafer is not exposed to ambient conditions (i.e., no breaking vacuum or maintaining an inert gas environment) after the UV exposure operations and before the copper barrier layer deposition, e.g., until after barrier or seed deposition. This may be accomplished by performing the UV exposing, barrier layer depositing and the copper seed layer deposition operations in the same semiconductor processing tool under a reduced pressure (vacuum) environment. In this way, dielectric damage induced by processing operations can be repaired and stabilized by subsequent deposition layers before a potentially damaging vacuum break for further processing.

Following trench fill, it becomes necessary to planarize the structure and remove the excess copper from the device. Planarization removes material down to the level of the top of dielectric layer 205. This results in an exposed pattern of conductive lines 221 in dielectric layer 205 and vias in dielectric layer 203. (See the cross-sectional view of FIG. 2C and the simplified top view of FIG. 2D.) Planarization may be accomplished by various techniques, and is typically conducted in a separate tool than that in which the UV processing and associated operations are performed in accordance with the present invention. These operations are briefly described here for purposes of context. The process planarization process typically involves some amount of CMP. It may also involve a combination of electropolishing, to remove most of the excess bulk copper, followed by CMP to remove the remaining copper down to the level of the top surface of dielectric layer 205.

### Apparatus

The present invention can be implemented in many different types of apparatus. In some embodiments, the apparatus will include one or more chambers (sometimes referred to as process modules) that house one or more semiconductor substrates (e.g., wafers) and are suitable for wafer processing. At least one chamber will include a UV source. A single chamber may have one or more stations and may be employed for one, some or all operations of the invention. Each chamber may house one or more wafers (substrates) for processing. The one or more chambers maintain the wafer in a defined position or positions (with or without motion within that position, e.g., rotation, vibration, or other agitation) during procedures of the invention. For certain operations in which the wafer temperature is to be controlled, the apparatus may include a controlled temperature wafer support, which may be heated, cooled, or both. The wafer support may also be controllable to provide the defined wafer positions within a process module. The wafer support may rotate, vibrate, or otherwise agitate the wafer relative to the UV source.

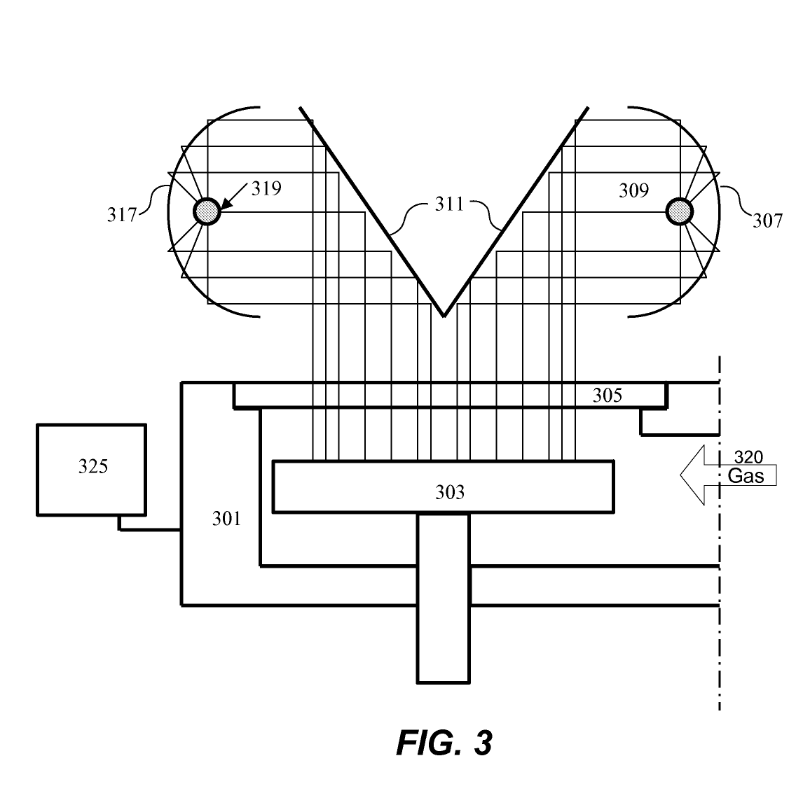

FIG. 3 depicts the arrangement of a UV light source suitable for implementation of the present invention. In this embodiment, a cold mirror reflector seeks to diminish the incidence of IR radiation on the wafer, while permitting UV radiation to be available for processing. For clarity, this figure depicts only one of the possible multiple processing stations available in an apparatus of this invention. Also, this figure omits depiction of the wafer for purposes of clarity, and shows a flood-type reflector. It will be apparent to those skilled in this art that the principles depicted in FIG. 3 may also be applied to a focused reflector.

Referring to FIG. 3, pedestal 303 is embedded into one station of a processing chamber 301. Window 305 is located appropriately above pedestal 303 to permit radiation of the wafer (not shown here) with UV output of the desired wavelengths from UV lamps 309 and 319. Suitable lamps for the UV light source may include, but are not limited to, mercury vapor or xenon lamps. Other suitable light sources include deuterium lamps, excimer lamps or lasers (e.g., excimer lasers and tunable variations of various lasers). Both lamps 309 and 319 are equipped with reflectors 307 and 317 which render their output into flood illumination. Reflectors 307 and 317 may themselves be made from “cold mirror” materials, i.e., they may also be designed to transmit IR and reflect UV radiation.

Radiation emanating directly from lamps 309 and 319 as well as that reflected from reflectors 307 and 317 is further incident upon a set of reflectors 311. These reflectors are also cold mirrors designed to reflect only those UV wavelengths that are desired for the purposes of curing the film on the wafer. All other radiation including visible and most particularly the IR is transmitted by this set of cold mirrors. Therefore the wafer is radiated only by those wavelengths that cause the desired effect on the film. It will be apparent to those skilled in this art that the specific angle, distance, and orientation of the cold mirror reflectors 311 with respect to the lamps 309 and 319 may be optimized to maximize the UV intensity incident on the wafer and to optimize the uniformity of its illumination.

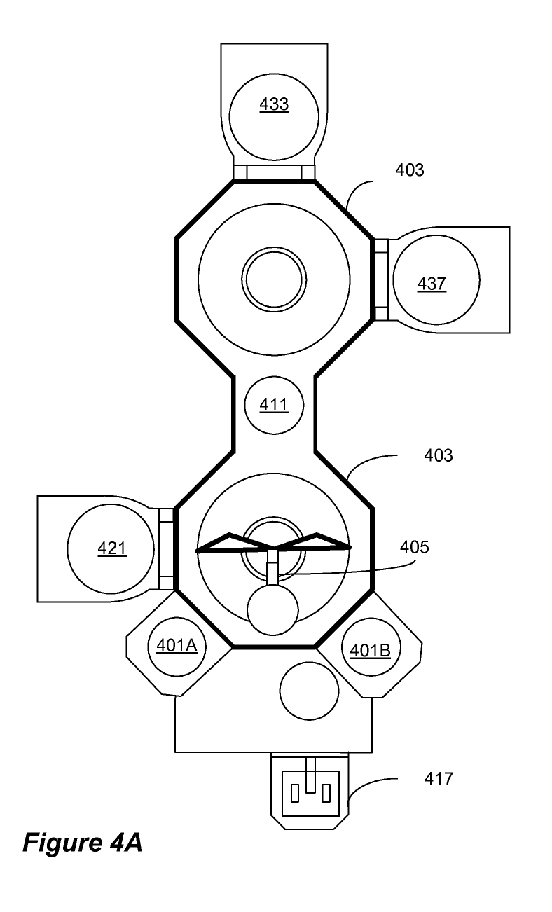

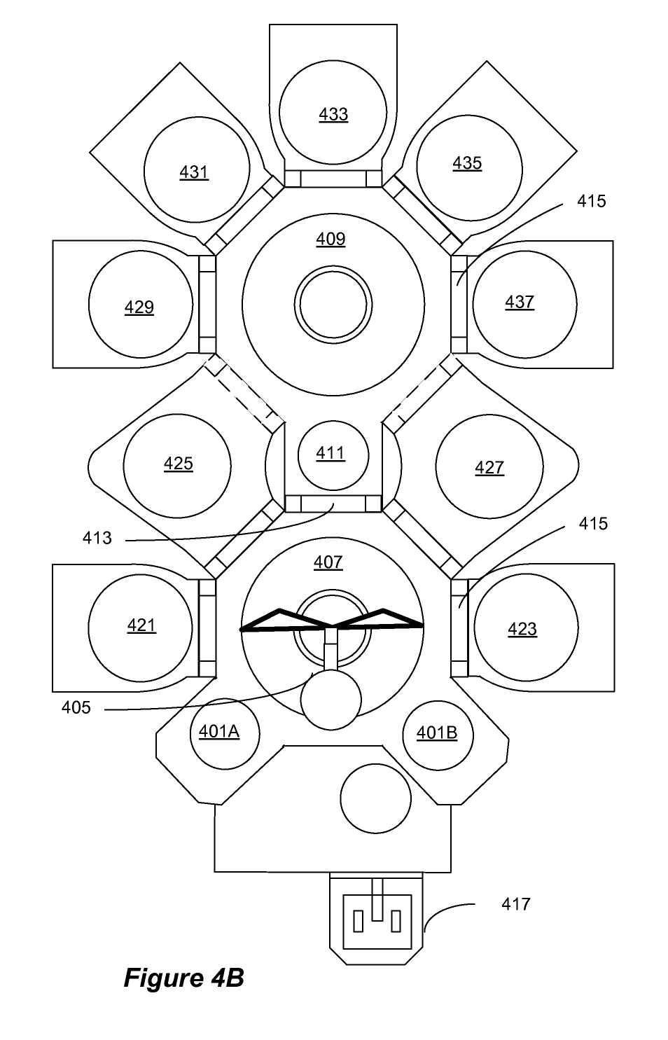

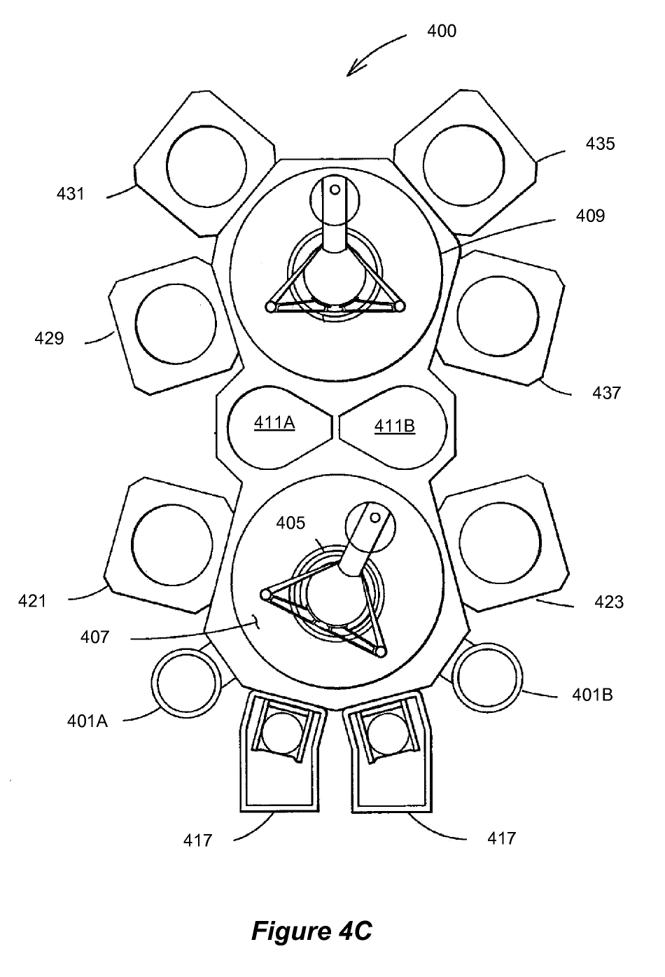

The chamber 301 is capable of holding a vacuum and/or containing gases at pressures above atmospheric pressure. For simplicity, only one station of one chamber 301 is shown. It is noted that in some embodiments, chamber 301 is one chamber in a multi-chambered apparatus such as the semiconductor processing tool of FIGS. 4A-C, although chamber 301 could alternatively be part of a stand-alone single chambered apparatus. In either case, the chamber(s) may have one or more than one station. In some embodiments of the present invention, the UV process modules have one station. Suitable apparatus for implementation of the invention may include configurations as described herein of INOVA, Sequel and SOLA systems from Novellus Systems, Inc. of San Jose, Calif., and Endura, Centura, Producer and Nanocure systems from Applied Materials of Santa Clara, Calif.

Note that the UV light source configuration of FIG. 3 is only an example of a suitable configuration. In general, it is preferable that the lamps are arranged to provide uniform UV radiation to the wafer. For example, other suitable lamp arrangements can include arrays of circular lamps concentrically or otherwise arranged, or lamps of smaller length arranged at 90 degree and 180 degree angles with respect to each other may be used. The light source(s) can be fixed or movable so as to provide light in appropriate locations on the wafer. Alternatively, an optical system, including for example a series of movable lenses, filters, and/or mirrors, can be controlled to direct light from different sources to the substrate at different times.

The UV light intensity can be directly controlled by the type of light source and by the power applied to the light source or array of light sources. Factors influencing the intensity of applied power include, for example, the number or light sources (e.g., in an array of light sources) and the light source types (e.g., lamp type or laser type). Other methods of controlling the UV light intensity on the wafer sample include using filters that can block portions of light from reaching the wafer sample. As with the direction of light, the intensity of light at the wafer can be modulated using various optical components such as mirrors, lenses, diffusers and filters. The spectral distribution of individual sources can be controlled by the choice of sources (e.g., mercury vapor lamp vs. xenon lamp vs. deuterium lamp vs. excimer laser, etc.) as well as the use of filters that tailor the spectral distribution. In addition, the spectral distributions of some lamps can be tuned by doping the gas mixture in the lamp with particular dopants such as iron, gallium, etc.

The apparatus may also include a source of a reactant gas 320, such as a gas phase source of methyl (—CH₃) groups and/or a reducing gas (e.g., NH₃ or H₂) or others as noted above.

In certain embodiments, a system controller 325 is employed to control process conditions during the UV treatment in accordance with the present invention. The controller will typically include one or more memory devices and one or more processors. The processor may include a CPU or computer, analog and/or digital input/output connections, stepper motor controller boards, etc.

In certain embodiments, the controller controls all of the activities of the apparatus. The system controller executes system control software including sets of instructions for controlling the timing, supply of gases, chamber pressure, chamber temperature, wafer temperature, UV wavelength, intensity and exposure time, and other parameters of a particular process. Other computer programs stored on memory devices associated with the controller may be employed in some embodiments.

Typically there will be a user interface associated with controller 325. The user interface may include a display screen, graphical software displays of the apparatus and/or process conditions, and user input devices such as pointing devices, keyboards, touch screens, microphones, etc.

The computer program code for controlling the processes can be written in any conventional computer readable programming language: for example, assembly language, C, C++, Pascal, Fortran or others. Compiled object code or script is executed by the processor to perform the tasks identified in the program.

Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the inventive processes. Examples of programs or sections of programs for this purpose include substrate positioning code, reducing gas control code, pressure control code, heater control code, and UV radiation control code. In one embodiment, the controller includes instructions for performing processes of the invention according to methods described above.

It should be understood that the apparatus depicted in FIG. 3 is only an example of a suitable UV process module and that other designs may be used. The semiconductor device should be transferred from the UV module to the barrier layer deposition module without an air break. This may be accomplished on multiple of single tools.

It should be understood that the apparatus depicted in FIG. 3 is only an example of a suitable UV process module and that other designs for other methods involved in previous and/or subsequent processes may be used. Examples of apparatus that may be suitable for implementing the present invention are also described in commonly assigned co-pending application Ser. Nos. 11/115,576 filed Apr. 26, 2005, 10/800,377 filed Mar. 11, 2004 and 10/972,084 filed Oct. 22, 2004, incorporated by reference herein in their entireties for all purposes.

FIG. 4A shows a schematic for a semiconductor processing system (apparatus) suitable for practicing the present invention. The processing apparatus includes load locks 401A and 401B, a transport module 403, a robot 405, and process modules (e.g., 421, 433, and 437) coupled to the transport module 403. At least one of the process modules is an ultraviolet (UV) process module. While FIG. 4A shows only three process modules, many more process modules may be configured on the semiconductor processing system at various positions, such as shown on FIG. 4B as 421, 423, 425, 427, 429, 431, 433, 435, and 437. Any one of these process modules may be a UV process module. Preferably, UV process modules are configured as chambers 429, 431, 433, 435, or 437.

As shown on FIG. 4B, the transport module 403 includes a load chamber 407, a transfer chamber 409, and a pass through chamber 411 located between the load chamber 407 and the transfer chamber 409. A wafer enters the system at loading station 417 and is transferred to a load lock 401A or 401B. The robot 405 is configured to transfer a wafer between the load locks (401A and 401B) and the load chamber 407. The process modules 421 and 423 are coupled to the load chamber 407 and are the first set of process modules. The process modules 429, 431, 433, 435, and 437 are coupled to the transfer chamber 409 and are the second set of process modules. A transfer chamber robot (not shown) is generally included to transfer a wafer between the different process modules in the second set and to and from the pass-through chamber 411. In a preferred embodiment, at least one of the second set of process modules is a UV process module.

Certain embodiments may include intermediate process modules 425 and 427. If no intermediate process modules are used, more than one pass-through chamber may be configured. Intermediate process modules 425 and 427 may be configured to couple with both the load chamber 407 and the transfer chamber 409. Wafer may enter or exit the intermediate process modules from the transfer chamber or the load chamber, thus bypassing the pass-through chamber 411. In certain embodiments, the intermediate process modules are not accessible from the transfer chamber. Instead, all wafers must enter the transfer chamber through the pass-through chamber 411. The pass-through chamber 411 may be isolated from the load chamber 407 by an isolation valve 413, which may be a slit valve or a gate valve. If isolated, the transfer chamber may be operating at a different pressure from that of the load chamber. Each process modules 421 to 437 are also configured with an isolation valve 415, as shown for process modules 437 and 423. As discussed above, intermediate process modules 425 and 427 may include more than one isolation valve 415, if access to both transfer and load chambers is configured. The isolation valves 415 allow each process module to operate at a pressure different from the chamber to which the process module is coupled. For certain processing operations, the additional vacuum or pressure may be useful. Additionally, the isolation valves prevent reactant gases and any gas emitted from the wafer to enter the transport module and contaminate other wafers.

The intermediate process modules 425 and 427 may be configured as a UV process module or as a degas module with an optional UV light source. During degassing, a wafer is heated to a defined temperature, e.g., about 200-300° C., and gases are allowed to diffuse away from the wafer. The wafer heating is normally accomplished through a controlled temperature pedestal and optionally heat transfer is aided by adding a gas, usually helium, to the backside of the wafer at a pressure of about 10 Torr. In certain embodiments where a UV light source is configured to the degas module, a part of the wafer heating may be accomplished through irradiation by UV light. The UV light would then not only heat the wafer, but also activate the surface reactions to repair the low-k dielectric damage, as explained above.

A large number of configurations and wafer transfer paths are possible with the semiconductor processing system. The configuration considerations include throughput, wafer transfer time, individual module process duration, robot availability, and flexibility. Ideally, process modules are located logically the wafer transfer paths such that initial and final wafer processing are performed in modules located no more than one transfer away from the load lock. Intermediate wafer processes should be located such that wafer transfer time is minimized. The system is configured so that every module has similar utilization rate, but preferably timed such that a module would not remain idle while waiting for a processed wafer to be removed. For example, if tantalum deposition takes typically 1 minute and UV exposure 2 minutes, the system should be configured with 2 UV process modules for every tantalum deposition module. Of course, the process duration in individual modules may change as the semiconductor device and films change, so that the configuration is preferably flexible enough to accommodate process changes. In certain embodiments, not all of the process modules are configured. For example, in some embodiments, process module 435, 425, or 429 may not be configured.

Generally, copper deposition module, pre-clean module, tantalum/tantalum nitride deposition module, UV process module, and degas modules may be configured on the system. Chemical vapor deposition (CVD), atomic layer deposition (ALD), or physical vapor deposition (PVD) modules may be configured. For example, one of modules 421 or 423 or both may be a copper deposition module configured to deposit copper seed layers. One or both modules of the first set of process modules may also deposit tantalum or tantalum nitride, or be a pre-clean module. The intermediate modules 425 and 427 are typically configured to be degas modules. However, in some cases, they may be hybrid degas/UV process modules or UV process modules. The pass-through module 411 may cool or heat the wafer in addition to allowing a wafer to pass-through. As discussed above, the second set of process modules 429 to 437 may include CVD, ALD, PVD modules, pre-clean modules, and UV process modules.

A typical configuration may be one pre-clean module, e.g., 429 or 437, one tantalum/tantalum nitride (Ta/TaN) module, e.g., 431 or 435, and the rest UV process modules in the second set of process modules (transfer chamber side). The degas chambers 425 and 427 may also include a UV light source. Coupled to the load chamber may be one or more copper deposition module at positions 421 or 423 with one or no UV process module. In this typical configuration, a wafer transfer path may be: Loading station 417 to load lock (401A or 401B) to degas module (425 or 427) to pre-clean module (429 or 437) to UV process module (433 or 431) to Ta/TaN deposition module 435 to pass-through module 411 to copper seed deposition module 421 to load lock (401B or 401A) to loading station 417.

In other configurations, no pre-clean modules are configured. Three UV process modules may be coupled to the transfer chamber with two barrier deposition (Ta/TaN) module. One or two copper deposition modules may be coupled to the load chamber. As discussed above, the number of modules depends on the process parameters and duration of each operation. In this configuration, the wafer transfer path may be: Loading station 417 to load lock (401A or 401B) to degas module (425 or 427) to UV process module (431, 433, or 435) to Ta/TaN deposition module (429 or 437) to pass-through module 411 to copper seed deposition module (421 or 423) to load lock (401A or 401B) to loading station 417.

FIG. 4C depicts an alternate system suitable for practicing the present invention. The wafer processing system of FIG. 4C includes no intermediate processing modules, but rather two pass-through modules 411A and 411B. Only four process modules may be configured to couple with the transfer chamber 409. A typical configuration in this alternate system may include one degas module, one Ta/TaN module, two UV process module, one copper deposition module, and one pre-clean module. If the pre-clean module is not used, one more UV process module or one more degas module may be configured.

In alternate configurations, the copper seed deposition modules may be coupled to the transfer chamber and the pre-clean module to the load chamber. A titanium or titanium nitride deposition module may also be used in some configurations either coupled to the transfer chamber or the load chamber. One skilled in the art would be able to configure a system based on process requirements to maximized throughput based on the configuration considerations discussed above.

While the invention has been described primarily in the context of damascene processing, it may also be applicable in other semiconductor processing contexts. Although the foregoing invention has been described in some detail for purposes of clarity of understanding, it will be apparent that certain changes and modifications may be practiced within the scope of the appended claims. It should be noted that there are many alternative ways of implementing both the process and compositions of the present invention. Accordingly, the present embodiments are to be considered as illustrative and not restrictive, and the invention is not to be limited to the details given herein.

1. A semiconductor substrate processing apparatus, comprising:
a. a load lock;
b. a transport module having a load chamber, a transfer chamber, and a pass-through chamber located between the load chamber and the transfer chamber, the load chamber being coupled to the load lock;
c. a robot configured to transfer a wafer between the load lock and the load chamber;
d. a UV process module coupled at least one of the load chamber and the transfer chamber; and
e. a metal deposition process module coupled to the transfer chamber.

2. The apparatus of claim 1, wherein the apparatus operates under vacuum such that a substrate is not exposed to ambient or other conditions that would damage a low-k dielectric during or between processing in the UV and metal deposition process modules.

3. The apparatus of claim 1, comprising a plurality of UV process modules.

4. The apparatus of claim 1, wherein the deposition process module comprises at least one of a barrier deposition module and a metal seed deposition module.

5. The apparatus of claim 1, wherein each process module is configured to process one wafer at a time.

6. The apparatus of claim 4, wherein the metal seed deposition module is a copper seed deposition module.

7. The apparatus of claim 1, further comprising a pre-clean module.

8. The apparatus of claim 1, wherein the metal deposition process module comprises at least one of a chemical vapor deposition module, an atomic layer deposition module, and a physical vapor deposition module.

9. The apparatus of claim 6, wherein the metal deposition process module further comprises a bulk copper deposition module.

10. The apparatus of claim 1, wherein the UV process module comprises
a. a temperature controlled substrate holder; and,
b. one or more UV light sources configured to generate UV radiation with a power density of about 500 mW-5 W/cm²;
wherein the UV light has a wavelength from about 150-500 nm.

11. The apparatus of claim 10, wherein the UV process module further comprises a gas inlet and a vacuum outlet.

12. The apparatus of claim 10, wherein the UV light source comprises an array of individual UV sources selected from a group consisting of mercury vapor lamps, xenon lamps, deuterium lamps, excimer lamps, excimer lasers, and combinations thereof.

13. The apparatus of claim 10, wherein the UV process module further comprises a reflector.

14. The apparatus of claim 10, wherein the UV process module further comprises a filter.

15. A method of forming a semiconductor device in a damascene processing, comprising:
a. receiving in a semiconductor processing apparatus a semiconductor device substrate comprising a carbon-containing low-k dielectric layer having formed therein a feature;
b. exposing the feature to UV radiation in a UV process module of the apparatus; and
c. depositing a barrier layer on the wafer in a process module of the apparatus; and,
wherein the substrate is not exposed to ambient conditions after exposing to UV radiation and before depositing the barrier layer.

16. The method of claim 15, further comprising depositing a copper seed layer on the substrate in a metal seed deposition process module of the apparatus;
wherein the wafer is not exposed to ambient conditions after exposing to UV radiation and before depositing the seed layer.

17. The method of claim 16, further comprising pre-cleaning the substrate and exposing the substrate to UV radiation after pre-cleaning.

18. The method of claim 17, further comprising degassing the substrate and exposing the wafer to UV radiation during degassing.

19. The method of claim 15, wherein the method is performed in the apparatus of claim 1.

20. An apparatus for repairing process-induced damage on a semiconductor device substrate, comprising:
(a) a semiconductor substrate processing apparatus, comprising:
a. a load lock;
b. a transport module having a load chamber, a transfer chamber, and a pass-through chamber located between the load chamber and the transfer chamber, the load chamber being coupled to the load lock;
c. a robot configured to transfer a wafer between the load lock and the load chamber;
d. a UV process module coupled at least one of the load chamber and the transfer chamber; and
e. a metal deposition process module coupled to the transfer chamber; and
(b) a controller comprising program instructions for conducting a method in accordance with claim 15.
